(19) United States
(12) Patent Application Publication
(10) Pub. No.: US 2002/0000923 A1
(43) Pub. Date: Jan. 3, 2002

(54) Switching power supply circuit

(76) Inventor: Yukihiro Nishikawa, Tokyo (JP)

Correspondence Address: KANESAKA AND TAKEUCHI, 1423 Powhatan Street, Alexandria, VA, 22314, US

(21) Appl. No.: 09/852,148

(22) Filed: May 10, 2001

(30) Foreign Application Priority Data
May 16, 2000 (JP) 2000-143175

(51) Int. Cl. H03M 11/00

(52) U.S. Cl. 341/22

(57) ABSTRACT

A diode bridge is connected to an AC power supply, and a series circuit comprised of a reactor and a main MOSFET is connected parallel to an output terminal of the diode bridge. A source terminal of an auxiliary MOSFET is connected to a drain terminal of the primary MOSFET to form a MOSFET series circuit. The MOSFETs are alternately turned on and off to allow capacitors connected parallel to the MOSFETs to perform charging and discharging operations. Thus, gentle voltage waveforms are generated when the MOSFETs are turned on and off, thereby reducing switching loss and noise.

### BACKGROUND OF THE INVENTION AND RELATED ART STATEMENT

The present invention relates to a switching power supply circuit that restrains noise and increases input power factor.

FIG. 3 shows a conventional example. This is a circuit comprised of a power-factor correction circuit section composed of a boost converter and a flyback DC/DC converter.

In FIG. 3, a noise-reducing line filter 12 is connected between an AC input terminal and a diode bridge 1, and a series circuit comprised of a reactor 13 and a MOSFET (Metal Oxide Semiconductor Field Effect Transistor) 5 is connected parallel to an output terminal of the diode bridge 1. Also, a series circuit comprised of a diode 17 and a capacitor 6 is connected parallel to the MOSFET 5 to form a power-factor correction circuit section. In addition, a series circuit comprised of primary windings of a transformer 16 and a MOSFET 4 is connected parallel to the capacitor 6, and a snubber circuit composed of a diode 18, a capacitor 19 and a resistor 20 is connected parallel to the primary windings of the transformer 16. Also, a diode 15 and a capacitor 11 are connected parallel to secondary windings of the transformer 16 to construct a DC/DC converter having DC outputs at opposite ends of the capacitor 11.

The operation of the boost converter will be described. When the MOSFET 5 is turned on, AC-side energy is stored in the reactor 13 via the diode bridge 1. When the MOSFET 5 is turned off, the energy stored in the reactor 13 is transferred to the capacitor 6 via the diode 17. At this time, the diode bridge 1 is conductive regardless of an instantaneous value of an AC voltage, so that an AC-side input current can be made to have a sinusoidal waveform to improve the power factor. The ON and OFF switching operations of the MOSFET 5 are controlled to maintain a constant voltage at the capacitor 6 and to give the AC input current a sinusoidal waveform.

The operation of the DC/DC converter section is described below. When the MOSFET 4 is turned on, energy stored in the capacitor 6 is stored as excitation energy for the flyback transformer 16. When the MOSFET 4 is turned off, this energy is transferred to the capacitor 11 via the diode 15. The ON and OFF switching operations of the MOSFET 4 are controlled to maintain the constant voltage at the capacitor 11.

In the conventional circuits, the MOSFET 5 of the boost converter and the MOSFET 4 of the DC/DC converter section have steep voltage waveforms when they are switched on or off, thereby increasing the loss and noise associated with the switching. This behavior characteristic makes it necessary to provide a large cooling device or component to reduce or eliminate a noise.

An object of the present invention is to provide a switching power supply circuit, wherein the noise associated with the switching of the power supply circuit is reduced, to thereby reduce switching loss.

Further objects and advantages of the invention will be apparent from the following description of the invention.

### SUMMARY OF THE INVENTION

To solve these problems, the invention in the first aspect provides a switching power supply circuit, wherein a diode bridge is connected to an AC power supply; a series circuit comprised of a reactor and a main MOSFET is connected parallel to an output terminal of the diode bridge; and a source terminal of an auxiliary MOSFET is connected to a drain terminal of the main MOSFET to construct a MOSFET series circuit. In the switching power supply circuit, a first capacitor is connected parallel to the MOSFET series circuit; a second or a third capacitor is connected to one or both of the MOSFETs; a series circuit comprised of a fourth capacitor and a fifth capacitor is connected parallel to the MOSFET series circuit; and only primary windings of a flyback transformer or both the primary windings of the flyback transformer and a reactor are connected to a connection between the fourth capacitor and the fifth capacitor and a connection in the MOSFET series circuit. A series-smoothing circuit composed of a diode and a capacitor is connected parallel to the secondary windings of the flyback transformer.

The invention in the second aspect provides a switching power supply circuit, wherein a diode bridge is connected to an AC power supply; a series circuit comprised of a reactor and a main MOSFET is connected parallel to an output terminal of the diode bridge; and a source terminal of an auxiliary MOSFET is connected to a drain terminal of the main MOSFET to construct a MOSFET series circuit; a first capacitor is connected parallel to the MOSFET series circuit; a second or third capacitor is connected to one or both of the MOSFETs; the capacitors and primary windings of a flyback transformer or the capacitors, the primary windings of the flyback transformer and the reactor are connected parallel to one of the MOSFETs; and a series-smoothing circuit composed of a diode and a capacitor is connected parallel to secondary the windings of the flyback transformer.

### BRIEF DESCRIPTION OF THE DRAWINGS

FIG. 1 is a circuit diagram showing a first embodiment of the present invention;

FIG. 2 is a view for clarifying the operation of the circuit in FIG. 1; and

FIG. 3 is a circuit diagram illustrating a conventional example.

### DETAILED DESCRIPTION OF PREFERRED EMBODIMENTS

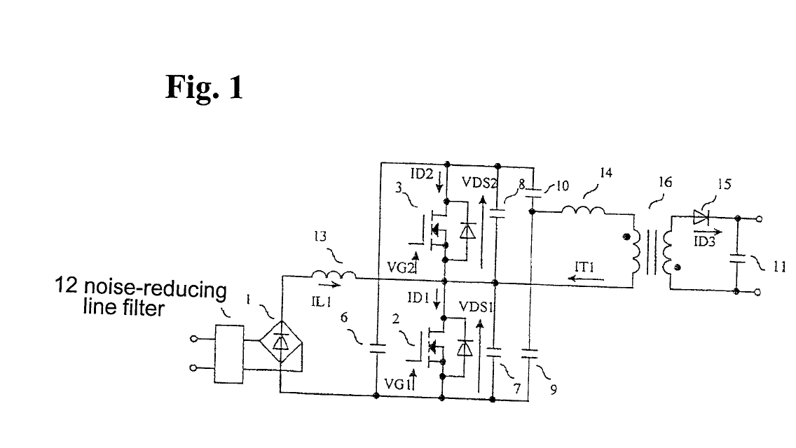

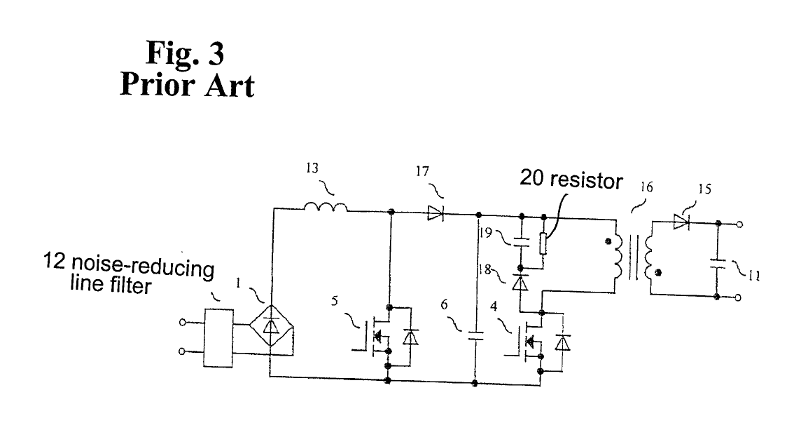

FIG. 1 is a circuit diagram showing an embodiment of the present invention. In this embodiment, a main MOSFET 2 is used in lieu of the MOSFETs 5 and 4 in the conventional circuits shown in FIG. 3; an auxiliary MOSFET 3 is connected in place of the diode 17; capacitors 7 and 8 are connected parallel to the MOSFETs 2 and 3, respectively; and a series circuit comprised of a capacitor 9 and a capacitor 10 is connected parallel to the capacitor 6. In addition, in place of the flyback transformer 16 and the MOSFET 4 connected parallel to the capacitor 6 in FIG. 3, a series circuit comprised of a reactor 14 and primary windings of a flyback transformer 16 is connected to a connection between the capacitor 9 and the capacitor 10, and a connection between the main MOSFET 2 and the auxiliary MOSFET 3. The capacitors 7 and 8 may be replaced by a parasitic capacity of MOSFETs 2 and 3, so that one or both can be omitted. One of the capacitors 9 and 10 can also be omitted.

The omission of one of the capacitors 9 and 10 is equivalent to the connection of a series circuit, parallel to the MOSFET 2 or 3, comprising the capacitor 9 or 10, the reactor 14, and the primary windings of the flyback transformer 16. Additionally, the reactor 14 may be replaced by the leakage inductance of the flyback transformer 16. It can thus be omitted. The main MOSFET 2 and auxiliary MOSFET 3 are PWM-controlled to be switched on and off with a constant dead time interposed between the ON and OFF operations in order to maintain a constant voltage at the capacitor 11. In addition, when an inductance value for the reactor 13 is selected so that current flows discontinuously through the reactor 13, the AC-side input current from the line filter 12 has a sinusoidal waveform, thus improving the input power factor.

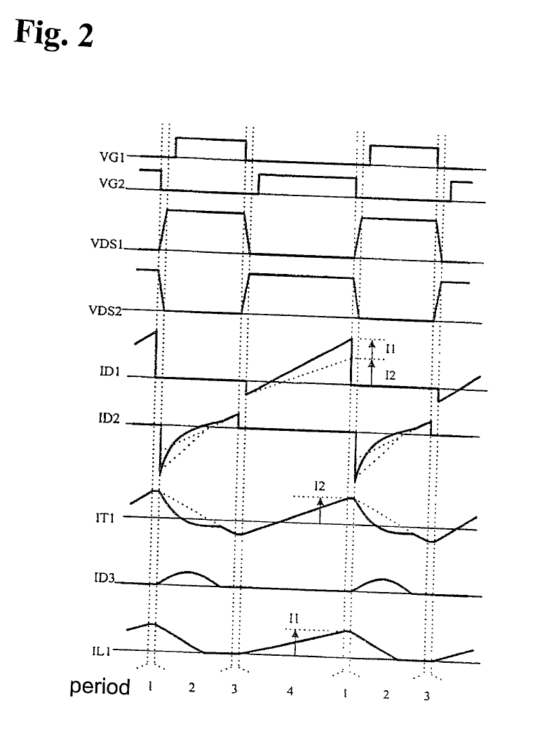

FIG. 2 shows operation waveforms from the circuit shown in FIG. 1. The waveforms will be explained in terms of periods 1 to 4.

Period 1

When the main MOSFET 2 is turned on to excite the reactor 13 and the flyback transformer 16, and is then turned off, the excitation current flowing through the reactor 13 and the flyback transformer 16 charges the capacitor 7. At this time, an increase in voltage at the main MOSFET 2 is restrained due to the speed that the capacitor 7 is charged, so that the main MOSFET is turned off with zero voltage, resulting in low switching loss. In addition, the voltage of the capacitor 8 decreases gradually with an increase in the voltage of the capacitor 7.

Period 2

Once the voltage of the capacitor 7 comes to equal to the voltage of the capacitor 6, the voltage of the capacitor 8 becomes zero, and a parasitic diode of the auxiliary MOSFET 3 becomes electrically conductive. At this point, the auxiliary MOSFET 3 is turned on with zero voltage, resulting in no turn-on loss. Moreover, since the voltage of the main MOSFET 2 is clamped to the voltage of the capacitor 6, almost no surge voltage is generated, and little noise occurs. The excitation energy stored in the reactor 13 is transferred to the capacitor 6 via the parasitic diode of the auxiliary MOSFET 3. A resonant action of the capacitors 9 and 10 and the reactor 14, constituting a resonant circuit, causes the excitation energy stored in the flyback transformer 16 to be emitted to the secondary side in such a manner that a current flowing through the diode 15 has a sinusoidal waveform. When the frequency of the resonant circuit is selected such that the current flowing through the diode 15 becomes zero before the auxiliary MOSFET 3 is turned off, the diode 15 is softly recovered to ensure that no surge voltage is generated and that little noise occurs. During this period, the flyback transformer 16 is reset by means of the voltage of the capacitor 10 to reverse the direction of the excitation current, so that a current flows through the auxiliary MOSFET 3 in a positive direction.

Period 3

If the auxiliary MOSFET 3 is turned off when a current starts to flow through the auxiliary MOSFET 3 in the positive direction, the reversed excitation current flowing through the flyback transformer 16 charges the capacitor 8. At this time, an increase in voltage at the auxiliary MOSFET 3 is restrained due to the speed that the capacitor 8 is charged, so that the auxiliary MOSFET 3 is turned off with zero voltage, resulting in low switching loss. In addition, the voltage of the capacitor 7 decreases gradually with an increase in voltage of the capacitor 8.

Period 4

Once the voltage of the capacitor 8 comes to equal to the voltage of the capacitor 6, the voltage of the capacitor 7 becomes zero, and a parasitic diode of the main MOSFET 2 becomes electrically conductive. At this point, the main MOSFET 2 is turned on with the zero voltage, resulting in no turn-on loss. Moreover, since the voltage of the auxiliary MOSFET 3 is clamped to the voltage of the capacitor 6, almost no surge voltage is generated, and little noise occurs. During this period, the reactor 13 is excited in the positive direction indicated by the arrow. The flyback transformer 16 is also excited in the positive direction indicated by the arrow. In the main MOSFET 2, the excitation currents flowing through the reactor 13 and through transformer 16 are superimposed.

The periods 1 to 4 are subsequently repeated to perform a switching operation. In addition, an operation for improving the power factor is achieved, regardless of the instantaneous value of the input voltage, by turning on and off the main MOSFET 2 to make diode bridge 1 electrically conductive after the reactor 13 has been excited and before it is reset.

Due to the charging and discharging operations of the capacitors connected parallel to the MOSFETs, the present invention makes it possible to slowly vary the voltage whether the main MOSFET or the auxiliary MOSFET is turned on and off, and the turn-on voltage of the MOSFET is clamped to the voltage of capacitor (6). Consequently, no surge voltage is generated, noise associated with the switching is reduced, and switching loss is minimized. This eliminates the need for a large cooling device or component to reduce or eliminate noise.

While the invention has been explained with reference to the specific embodiments of the invention, the explanation is illustrative and the invention is limited only by the appended claims.

What is claimed is:

1. A switching power supply circuit comprising:
a diode bridge connected to an AC power supply and having an output terminal,
a series circuit comprised of a reactor and a main MOSFET with a drain terminal connected parallel to the output terminal of the diode bridge,
an auxiliary MOSFET with a source terminal connected to the drain terminal of the main MOSFET to construct a MOSFET series circuit,
a first capacitor connected parallel to the MOSFET series circuit,
at least one second capacitor connected to at least one of the main and auxiliary MOSFETs,
a series circuit comprised of a third capacitor and a fourth capacitor connected parallel to the MOSFET series circuit,
a flyback transformer having primary windings and secondary windings, said primary windings being connected to a connection between the third capacitor and the fourth capacitor and a connection in said MOSFET series circuit, and
a series-smoothing circuit composed of a diode and a capacitor connected parallel to the secondary windings of the flyback transformer.

2. A switching power supply circuit according to claim 1, further comprising a reactor connected in series to the primary windings of the flyback transformer, said reactor and primary windings being connected between said two connections.

3. A switching power supply circuit according to claim 2, wherein said main and auxiliary MOSFETs include one second capacitor, respectively.

4. A switching power supply circuit comprising:
a diode bridge connected to an AC power supply and having an output terminal,
a series circuit comprised of a reactor and a main MOSFET with a drain terminal connected parallel to the output terminal of the diode bridge,
an auxiliary MOSFET with a source terminal connected to the drain terminal of the main MOSFET to construct a MOSFET series circuit,
a first capacitor connected parallel to the MOSFET series circuit,
at least one second capacitor connected to at least one of the main and auxiliary MOSFETs,
a flyback transformer having primary windings and secondary windings,
a series connection formed of said primary windings and a third capacitor, and connected parallel to one of the main MOSFET and the auxiliary MOSFET, and
a series-smoothing circuit composed of a diode and a capacitor connected parallel to the secondary windings of the flyback transformer.

5. A switching power supply circuit according to claim 4, further comprising a reactor connected in series to the primary windings of the flyback transformer, said reactor being connected in series to the series connection.

6. A switching power supply circuit according to claim 5, wherein said main and auxiliary MOSFETs include one second capacitor, respectively.
